(19) United States
(12) Patent Application Publication
(10) Pub. No.: US 2013/0081862 A1
(43) Pub. Date: Apr. 4, 2013

(54) WIRING SUBSTRATE AND METHOD OF MANUFACTURING THE SAME

(71) Applicant: NGK SPARK PLUG CO., LTD., Nagoya-shi (JP)

(72) Inventors: Takahiro HAYASHI, Komaki-shi (JP); Seiji MORI, Konan-shi (JP); Tatsuya ITO, Kakamigahara-shi (JP)

(73) Assignee: NGK SPARK PLUG CO., LTD., Nagoya-shi (JP)

(21) Appl. No.: 13/633,421

(22) Filed: Oct. 2, 2012

(30) Foreign Application Priority Data
Oct. 4, 2011 (JP) 2011-220208
Mar. 13, 2012 (JP) 2012-055808

(51) Int. Cl. H05K 1/03; H05K 3/22; H05K 1/09

(52) U.S. Cl. 174/255; 174/258; 174/257; 228/203

(57) ABSTRACT

Embodiments of the present invention provide a wiring substrate which is excellent in terms of the reliability of connection between the wiring substrate and a semiconductor chip. In some embodiments the wiring substrate comprises a first build-up layer in which resin insulation layers and conductor layers are laminated alternately. The outermost conductor layer can include a plurality of connection terminal portions to which a semiconductor chip is flip-chip connected. The plurality of connection terminal portions can be exposed through openings of a solder resist layer. Each of the connection terminal portions includes a connection region to which a connection terminal of the semiconductor chip is to be connected, and a wiring region which extends in a planar direction from the connection region and which is narrower than the connection region. The surface of the wiring region has a solder wettability lower than that of the surface of the connection region.

### CROSS REFERENCE TO RELATED APPLICATIONS

The present application claims priority from Japanese Patent Application No. 2011-220208, which was filed on Oct. 4, 2011, and Japanese Patent Application No. 2012-055808, which was filed on Mar. 13, 2012, the disclosures of which are herein incorporated by reference in their entirety.

### BACKGROUND OF THE INVENTION

1. Field of the Invention

The present invention relates to a wiring substrate which has a plurality of connection terminal portions to which a semiconductor chip is flip-chip connected, and to a method of manufacturing the same.

2. Description of Related Art

In association with a recent increasing tendency toward higher operation speed and higher functionality of semiconductor integrated circuit devices (semiconductor chips) used as, for example, microprocessors of computers, the number of terminals has increased, and the pitch between the terminals has tended to become narrower. Generally, a large number of connection terminals are arrayed on the bottom surface of a semiconductor chip and flip-chip-connected to a plurality of connection terminal portions formed on a wiring substrate. See, for example, Patent Document 1.

More specifically, the connection terminal portions of the wiring substrate are constituted by a conductor layer mainly formed of copper, and their copper surfaces are exposed. Connection terminals of a semiconductor chip are connected to the copper surfaces through solder bumps or the like.

In the wiring substrate disclosed in Patent Document 1, each connection portion conductor trace (connection terminal portion) has a wiring trace (wiring region) and a connection pad (connection region) which is wider than the wiring trace. At the time of solder connection, the surfaces of the wiring trace and the connection pad are coated with solder paste, which is then melted through application of heat. At that time, due to the surface tension of melted solder in a liquid state, the melted solder moves to the connection pad side and remains there. Therefore, the connection pads can be reliably solder-connected to the connection terminals of the semiconductor chip.

### RELATED ART DOCUMENTS

### Patent Document

Patent Document 1 is Japanese Patent No. 3420076.

### BRIEF SUMMARY OF THE INVENTION

However, in the case where a thermal history (involving a temperature equal to or higher than the melting point of solder) is applied to a wiring substrate in a reliability evaluation test performed after mounting of a semiconductor chip on the substrate, the following problem arises. Namely, in the case of the wiring substrate disclosed in Patent Document 1, although the melted solder is collected to the connection pad side by making use of the surface tension of the melted solder, a thin film of solder remains on the surface of the wiring trace. Accordingly, the solder wettability of the wiring trace is equal to that of the connection pad. Therefore, when a thermal history is applied to the wiring substrate after formation of solder connection, the solder collected on the connection pad side flows to the wiring trace side. In such a case, the amount of the solder on the connection pad side decreases. As a result, the semiconductor chip suffers an open failure. Particularly, in the case where the pitch between terminals is decreased so as to increase the mounting density of a wiring substrate, since the amount of solder to be used decreases with the size of the terminals, the incidence of open failure attributable to thermal history increases.

The present invention has been conceived in view of the above problem, and an object of the invention is to provide a wiring substrate which can prevent outflow of solder from connection regions even when a thermal history is applied to the wiring substrate, to thereby realize highly reliable connection between the wiring substrate and a semiconductor chip. Another object of the present invention is to provide a wiring substrate manufacturing method which can manufacture a wiring substrate which is excellent in terms of the reliability of connection between the wiring substrate and a semiconductor chip.

A means for solving the above problems (Means 1) is a wiring substrate comprising a laminate in which a plurality of insulation layers and a plurality of conductor layers are laminated alternately, the outermost conductor layer of the laminate including a plurality of connection terminal portions which are arranged along the periphery of a semiconductor chip mounting region and to which a semiconductor chip is flip-chip connected, the plurality of connection terminal portions being disposed in openings formed in the outermost insulation layer of the laminate, wherein each of the connection terminal portions includes a connection region to which a connection terminal of the semiconductor chip is to be connected via solder, and a wiring region which extends in a planar direction from the connection region and which is narrower than the connection region; and the surface of the wiring region has a solder wettability lower than that of the surface of the connection region.

According to the invention described in Means 1, in each connection terminal portion, the connection region to which a connection terminal of a semiconductor chip is to be connected is wider than the wiring region. Therefore, a sufficiently large area can be provided for solder connection. Also, since the surface of the wiring region is lower in solder wettability than the surface of the connection region, even when a thermal history is applied to the wiring substrate after mounting of the semiconductor chip on the substrate, problems such as outflow of solder from the connection region to the wiring region do not occur, and solder on the connection region can be retained reliably. Therefore, highly reliable connection can be established between the wiring substrate and the semiconductor chip. Notably, the “solder wettability of the surface” is measured by the following method. First, the compositions of the surface of the wiring region and the surface of the connection region are identified by performing metal analysis and organic analysis. Examples of methods for performing metal analysis and organic analysis include EPMA, XPS, AES, FE-AES, FTIR, SIMS, and TOF-SIMS. Subsequently, a substrate for evaluation is prepared by reproducing a wiring substrate which includes connection terminal portions having the compositions identified by these analytical methods while scaling up the wiring substrate, and the solder wettabilities of the surface of the wiring region and the surface of the connection region are evaluated by a measurement method according to JIS 23197.

Notably, in each connection terminal portion of the wiring substrate, the wiring region may extend from both of opposite sides of the connection region with respect to a planar direction, or may extend from one of the opposite sides of the connection region with respect to the planar direction. Also, no limitation is imposed on the shape of the connection region, so long as the connection region is wider than the wiring region. Specifically, as viewed from above, the connection region may have a rhombic shape, a circular shape (e.g., completely round or elliptical), the shape of a quadrangle (square or rectangle) with four rounded corners, the shape of a quadrangle with four chamfered corners, or the shape of a polygon having three or more corners (e.g., triangle, quadrangle, pentagon, hexagon, or the like). Namely, the shape of the connection region as viewed from above can be freely changed in accordance with the design of the wiring substrate, the shape of the terminals of the semiconductor chip, or the like. Here, the dimension of the connection region measured along the extension direction of the wiring region is defined as the “length” and the dimension of the connection region measured along a direction perpendicular to the extension direction of the wiring region is defined as the “width.” The length of the connection region may be set to be greater than the width thereof. Alternatively, the width of the connection region may be set to be greater than the length thereof. Also, the length of the widest portion of the connection region is defined as the “the widest portion length.” Preferably, the widest portion length is rendered short in order to form solder bumps having a sufficient height.

Preferably, the wiring substrate is configured as follows. A first metal layer is formed on the surfaces of the connection region and the wiring region. The first metal layer is exposed on the surface of the wiring region. A second metal layer is formed on the surface of the connection region via the first metal layer such that the second metal layer is exposed. The surface of the first metal layer has a solder wettability lower than that of the surface of the second metal layer. By virtue of this configuration, the second metal layer which is high in solder wettability is exposed on the surface of the connection region, and the first metal layer which is low in solder wettability is exposed on the surface of the wiring region. Accordingly, even when a thermal history is applied to the wiring substrate after mounting of a semiconductor chip on the substrate, problems such as outflow of solder from the connection region to the wiring region do not occur. Therefore, highly reliable connection can be established between the wiring substrate and the semiconductor chip.

Preferably, the first metal layer is an intermetallic compound layer including a metal which constitutes the connection terminal portions and a metal which constitutes the second metal layer. In this case, the intermetallic compound layer, which serves as the first metal layer, can be readily formed on the surface of the connection terminal portion by performing heat treatment, etc., after formation of the second metal layer on the connection terminal portion.

Preferably, the metal which constitutes the connection terminal portions is copper or a copper alloy, the metal which constitutes the second metal layer is a solder material including metal which can be used as a solder material, other than copper, and the intermetallic compound layer is an alloy layer of copper and the solder material including metal. In this case, since each connection terminal is formed of copper or a copper alloy, the connection resistance between the wiring substrate and the semiconductor chip can be lowered. Also, through use of a solder material including metal (e.g., low melting point metal) which can be used as a solder material, the alloy layer can be readily formed by heat treatment at a relatively low temperature.

Specifically, preferably, the metal which constitutes the second metal layer is tin, and the intermetallic compound layer, which serves as the first metal layer, is an alloy layer of copper and tin. Furthermore, preferably, the second metal layer is a tin mass layer formed as a result of collection of melted tin. By virtue of this configuration, the connection region where the tin mass layer is exposed has a high solder wettability, and the wiring region where the alloy layer of copper and tin is exposed has a low solder wettability. Accordingly, it is possible to reliably avoid the occurrence of problems, such as outflow of solder from the connection region to the wiring region, which could otherwise occur due to a thermal history applied to the wiring substrate, and to establish a highly reliable connection between the wiring substrate and the semiconductor chip. Moreover, since copper or a copper alloy which constitutes the connection terminal portions and tin which constitutes the second metal layer are relatively inexpensive metals, the production cost of the wiring substrate can be reduced.

In the wiring substrate, preferably, the side surface of each connection terminal portion is covered by the insulation layer. By virtue of this configuration, only the upper surface of the connection terminal portion is exposed in the connection region and the wiring region, and the area ratio of the exposed surface of the connection region to the exposed surface of the wiring region can be increased. Therefore, the melted solder material including metal (e.g., tin) can be reliably collected to the surface of the connection region having a large area.

The first metal layer has a surface roughness greater than that of the second metal layer. In general, after mounting of a semiconductor chip on the wiring substrate, the gap between the semiconductor chip and the wiring substrate is sealed through use of an underfill material. In such a case, the degree of adhesion between the surface of the wiring region and the underfill material can be increased by increasing the surface roughness of the first metal layer, whereby a sufficient degree of sealing can be provided. Also, since it is unlikely that a gap will form between the surface of the wiring region and the underfill material, it is possible to reliably avoid the occurrence of problems, such as outflow of solder from the connection region to the wiring region, which would otherwise occur due to thermal history.

Also, preferably, the second metal layer is thicker than the first metal layer. In this case, it is possible to form reliable solder connection between the connection region of each connection terminal portion and a corresponding connection terminal of the semiconductor chip.

Further still, as viewed from above, the connection region can have a rhombic shape, a circular shape, a shape of a quadrangle with four rounded corners, a shape of a quadrangle with four chamfered corners, or a shape of a polygon having three or more corners.

The terminal pitch of the plurality of connection terminal portions formed on the wiring substrate is preferably set to 80 μm or less, and more preferably to 40 μm or less. In the case where the mounting density of the wiring substrate is increased by narrowing the terminal pitch as described above, the area of the connection region decreases, and the mount of solder to be used decreases. In the present invention, the solder wettability of the connection region is rendered higher than that of the wiring region such that solder can be reliably retained in the connection region. Therefore, even in the above-described case where the mounting density of the wiring substrate is increased, a highly reliable connection can be established between the wiring substrate and the semiconductor chip.

In the wiring substrate, preferably, the plurality of connection terminal portions are arranged such that their wiring regions extend parallel to one another. In this case, the connection regions of two connection terminal portions which are adjacent to each other in the arrangement direction are shifted from each other in the direction (the extension direction of the wiring region) perpendicular to the arrangement direction of the connection terminal portions such that the positions of the connection regions do not overlap in the arrangement direction. This configuration enables the plurality of connection terminal portions each including the wide connection region to be provided in a smaller space. Therefore, the mounting density of the wiring substrate can be increased.

Although the wiring substrate of Means 1 can be a ceramic wiring substrate in which ceramic insulation layers are used, preferably, the wiring substrate is an organic wiring substrate in which resin insulation layers are used. When the wiring substrate is an organic wiring substrate, density of wiring can be increased.

Preferably, the resin insulation layers are formed through use of a build-up material which is mainly formed of thermosetting resin. Examples of the material used for forming the resin insulating layers include thermosetting resins, such as epoxy resin, phenol resin, urethane resin, silicone resin, and polyimide resin. Alternatively, there may be used a composite material of any of these resins and glass fibers (glass woven fabric or glass unwoven fabric) or organic fibers such as polyamide fibers, or a resin-resin composite material formed by impregnating a three-dimensional network fluorine-based resin matrix, such as an interconnected porous PTFE, with a thermosetting resin, such as epoxy resin.

Preferably, the conductor layers of the organic wiring substrate are mainly formed of copper. In this case, the conductor layers are formed by a known process such as a subtractive method, a semi-additive method, or a full-additive method. Specifically, for example, etching of copper foil, electroless copper plating, electro copper plating, or the like process is applied. Notably, the conductor layers may be formed through etching of a thin film formed by spattering, CVD, or the like, or through printing of electrically conductive paste or the like.

Examples of the semiconductor chip include IC chips used as microprocessors of microcomputers, and other IC chips such as DRAM (Dynamic Random Access Memory) and SRAM (Static Random Access Memory).

A means for solving the above problems (Means 2) is a method of manufacturing the above-described wiring substrate, the method comprising a preliminary metal layer forming step of forming, on the surfaces of the connection region and the wiring region, a preliminary metal layer including the solder material including metal and a flux or a preliminary metal layer which includes the solder material including metal and a flux applied onto the solder material including metal, and a heating step of performing, after the preliminary metal layer forming step, heating at a temperature higher than the melting point of the solder material including metal so as to form the first alloy layer, which includes copper and the solder material including metal, on the surfaces of the connection region and the wiring region, and to allow the solder material including metal melted on the surface of the wiring region to collect on the surface of a connection region to thereby form the second metal layer.

According to the invention described in Means 2, after a preliminary metal layer is formed on the surfaces of the connection region and the wiring region in the preliminary metal layer forming step, in the heating step, heating is performed such that the temperature of the preliminary metal layer becomes higher than the melting point of the solder material including metal. Thus, the solder material including metal of the preliminary metal layer is melted. At that time, an alloy layer which is an intermetallic compound layer of copper and the solder material including metal is formed on the surfaces of the connection region and the wiring region as the first metal layer. The melted solder material including metal collects on the wide connection region due to its surface tension, to thereby form the second metal layer. Also, since the melted solder material including metal flows from the wiring region to the connection region, the alloy layer is exposed on the surface of the wiring region. As a result of performance of the heating step, the solder material including metal having a high solder wettability is exposed on the surface of the connection region, and the alloy layer having a low solder wettability is exposed on the surface of the wiring region. Accordingly, even when a thermal history is applied to the wire substrate after mounting of a semiconductor chip on the substrate, it is possible to reliably avoid the occurrence of problems such as outflow of solder from the connection region to the wiring region. Thus, it is possible to obtain a wiring substrate which is excellent in terms of the reliability of connection between the wiring substrate and the semiconductor chip.

A means for solving the above problems (Means 3) is a method of manufacturing the above-described wiring substrate, the method comprising a preliminary metal layer forming step of forming, on the surfaces of the connection region and the wiring region, a preliminary metal layer which includes the tin plating layer and a flux applied thereon, and a heating step of performing, after the preliminary metal layer forming step, heating at a temperature higher than the melting point of tin so as to form the first alloy layer, which includes copper and tin, on the surfaces of the connection region and the wiring region, and to allow the tin melted on the surface of the wiring region to collect on the surface of the connection region to thereby form a tin mass layer as the second metal layer.

According to the invention described in Means 3, after a preliminary metal layer which includes a tin plating layer and flux applied thereon is formed on the surfaces of the connection region and the wiring region in the preliminary metal layer forming step, in the heating step, heating is performed such that the temperature of the preliminary metal layer becomes higher than the melting point of tin and the tin is melted. At that time, an alloy layer of copper and tin is formed on the surfaces of the connection region and the wiring region. The melted tin collects on the wide connection region due to its surface tension, to thereby form a tin mass layer. Also, since the melted tin flows from the wiring region to the connection region, the alloy layer is exposed on the surface of the wiring region. As a result of performance of the heating step, the tin mass layer having a high solder wettability is exposed on the surface of the connection region, and the alloy layer having a low solder wettability is exposed on the surface of the wiring region. Accordingly, even when a thermal history is applied to the wire substrate after mounting of the semiconductor chip on the substrate, it is possible to reliably avoid the occurrence of problems such as outflow of solder from the connection region to the wiring region. Thus, it is possible to obtain a wiring substrate which is excellent in terms of the reliability of connection between the wiring substrate and the semiconductor chip.

The wiring substrate may have a main surface on which the connection terminal portions are formed, and a back surface which is provided on the side opposite the main surface and on which a plurality of external connection terminals are formed. Solder bumps are disposed on the external connection terminals. In this case, preferably, the heating step is realized by a solder reflow step of providing solder bumps on the external connection terminals. In this case, the heating step and the reflow step, which has conventionally been performed for manufacture of substrates, are not required to be performed in different heat treatment steps. Therefore, the manufacturing cost of the wiring substrate can be reduced.

### BRIEF DESCRIPTION OF THE DRAWINGS

Illustrative aspects of the invention will be described in detail with reference to the following figures wherein:

FIG. 1 is a plan view showing an organic wiring substrate of one embodiment.

FIG. 2 is an enlarged sectional view showing the organic wiring substrate of the embodiment.

FIG. 3 is an explanatory view showing a method of manufacturing the organic wiring substrate of the embodiment.

FIG. 4 is an explanatory view showing the method of manufacturing the organic wiring substrate of the embodiment.

FIG. 5 is an explanatory view showing the method of manufacturing the organic wiring substrate of the embodiment.

FIG. 6 is an explanatory view showing the method of manufacturing the organic wiring substrate of the embodiment.

FIG. 7 is an explanatory view showing the method of manufacturing the organic wiring substrate of the embodiment.

FIG. 8 is an explanatory view showing the method of manufacturing the organic wiring substrate of the embodiment.

FIG. 9 is an explanatory view showing the method of manufacturing the organic wiring substrate of the embodiment.

FIG. 10 is an explanatory view showing the method of manufacturing the organic wiring substrate of the embodiment.

FIG. 11 is an explanatory view showing the method of manufacturing the organic wiring substrate of the embodiment.

FIG. 12 is an explanatory view showing the method of manufacturing the organic wiring substrate of the embodiment.

FIG. 13 is an explanatory view showing the method of manufacturing the organic wiring substrate of the embodiment.

FIG. 14 is an explanatory view showing the method of manufacturing the organic wiring substrate of the embodiment.

FIG. 15 is an explanatory view showing the method of manufacturing the organic wiring substrate of the embodiment.

FIG. 16 is an enlarged plan view showing connection terminal portions according to another embodiment.

FIG. 17 is an enlarged plan view showing connection terminal portions according to another embodiment.

FIG. 18 is an enlarged plan view showing connection terminal portions according to another embodiment.

FIG. 19 is an enlarged plan view showing connection terminal portions according to another embodiment.

FIG. 20 is an enlarged plan view showing connection terminal portions according to another embodiment.

### DETAILED DESCRIPTION OF EXEMPLARY EMBODIMENTS OF THE INVENTION

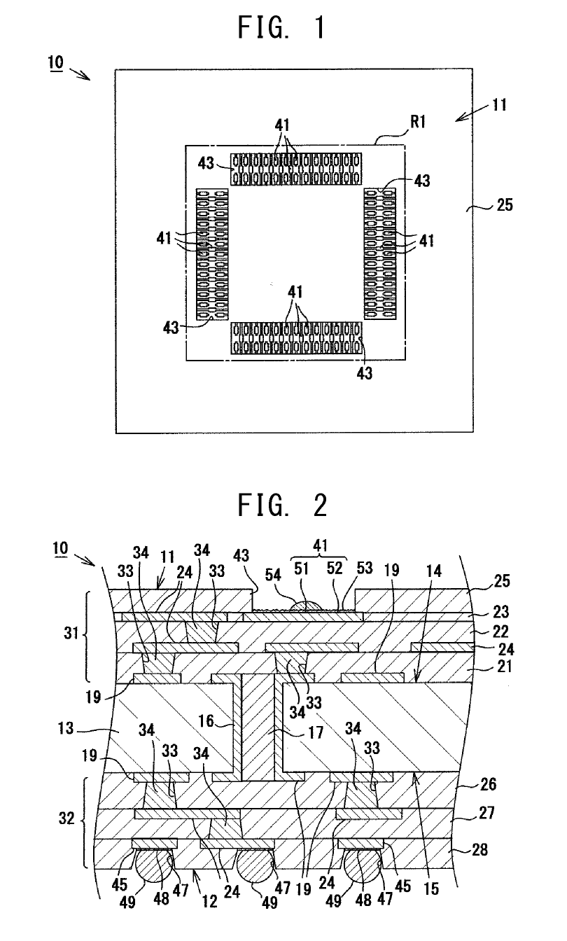

An organic wiring substrate, which is one embodiment of the wiring substrate of the present invention, will next be described in detail with reference to the drawings. FIG. 1 is a plan view showing an organic wiring substrate of the present embodiment. FIG. 2 is an enlarged sectional view showing a main portion of the organic wiring substrate.

As shown in FIGS. 1 and 2, the organic wiring substrate 10 of the present embodiment is a wiring substrate having a peripheral structure, and has a main surface 11, which serves as a semiconductor chip mounting surface, and a back surface 12 opposite the main surface 11. Specifically, the organic wiring substrate 10 includes a rectangular plate-like core substrate 13, a first build-up layer 31 formed on a main surface 14 (upper surface in FIG. 2) of the core substrate 13, and a second build-up layer 32 formed on a back surface 15 (lower surface in FIG. 2) of the core substrate 13.

The core substrate 13 of the present embodiment is formed of, for example, a resin insulation material (glass epoxy material) formed by impregnating glass cloth (i.e., a reinforcing material) with an epoxy resin. The core substrate 13 has a plurality of through-hole conductors 16 extending therethrough between the main surface 14 and the back surface 15. The internal spaces of the through-hole conductors 16 are filled with plugs 17 formed of, for example, an epoxy resin. Conductor layers 19 of copper are formed in respective patterns on the main surface 14 and the back surface 15 of the core substrate 13, and are electrically connected to the through-hole conductors 16.

The first build-up layer 31 formed on the main surface 14 of the core substrate 13 is a laminate having a structure in which a plurality of resin insulation layers 21, 22, 23 (insulation layers) made of a thermosetting resin (epoxy resin) and a plurality of conductor layers 24 made of copper are laminated alternately. In the first build-up layer 31, the outermost conductor layer 24 includes a plurality of connection terminal portions 41, which are arranged along the periphery of a semiconductor chip mounting region R1 in order to enable a semiconductor chip (not shown) to be flip-chip connected to the connection terminal portions 41. Further, a solder resist layer 25 is provided as the outermost insulation layer in the first build-up layer 31. A plurality of slit-like openings 43 are formed in the solder resist layer 25 at positions corresponding to the four sides of the semiconductor chip mounting region R1. A plurality of connection terminal portions 41 are formed in each of the openings 43 of the solder resist 25.

In the present embodiment, the plurality of connection terminal portions 41 are provided on the upper surface of the resin insulation layer 22, and the resin insulation layer 23 is provided such that it covers the side surfaces of the connection terminal portions 41. Via holes 33 and filled-via conductors 34 are provided in the resin insulation layers 21 and 22. The via conductors 34 are electrically connected to the conductor layers 19 and 24, and to the connection terminal portions 41.

A semiconductor chip to be mounted on the wiring substrate 10 of the present embodiment has connection terminals of, for example, a Cu pillar structure. Notably, a semiconductor chip whose connection terminals have an Au-plated bump structure or an Au stud structure rather than such a Cu pillar structure may be flip-chip mounted.

The second build-up layer 32 formed on the back surface 15 of the core substrate 13 has a structure substantially identical with that of the above-described first build-up layer 31. Namely, the second build-up layer 32 has a structure in which resin insulation layers 26 and 27 and conductor layers 24 are laminated alternately. In the second build-up layer 32, the outermost conductor layer 24 includes a plurality of external connection terminals 45 for connection to a motherboard (not shown). Via holes 33 and filled-via conductors 34 are also formed in the resin insulation layers 26 and 27. The via conductors 34 are electrically connected to the conductor layers 19 and 24, and to the external connection terminals 45. Further, a solder resist layer 28 is provided as the outermost insulation layer in the second build-up layer 32. Openings 47 for exposing the external connection terminals 45 are formed in the solder resist layer 28 at predetermined locations. Also, the lower surfaces of the external connection terminals 45 exposed to the outside through the openings 47 are covered by a plating layer 48 (e.g., tin plating layer). A plurality of solder bumps 49, which are electrically connectable to the unillustrated motherboard, are disposed on the lower surfaces of the external connection terminals 45. The organic wiring substrate 10 is mounted on the unillustrated motherboard through the solder bumps 49.

Next, the specific structure of the connection terminal portions 41 formed in the first build-up layer 31 on the side toward the substrate main face 11 will be described in detail with reference to FIG. 15.

As shown in FIG. 15, each connection terminal portion 41 has a connection region 51 to which the corresponding connection terminal of the semiconductor chip is to be connected through solder, and a wiring region 52 which extends in a planar direction from the connection region 51 and which has a width smaller than that of the connection region 51. Each connection terminal portion 41 (the connection region 51 and the wiring region 52) is mainly formed of copper, and an Sn—Cu alloy layer 53 formed of tin and copper (an intermetallic compound layer serving as a first metal layer) is formed on the surface of the connection terminal portion 41 (see FIG. 2). This alloy layer 53 is exposed on the surface of the wiring region 52. A tin mass layer 54 (a second metal layer) is formed on the surface of the connection region 51 via the Sn—Cu alloy layer 53 in an exposed state.

As shown in FIG. 2, the tin mass layer 54 has a dome-like shape which is formed as a result of collection of melted tin (solder material including metal) on the connection region 51. The tin mass layer 54 has a thickness greater than that of the Sn—Cu alloy layer 53. Also, fine protrusions and depressions are formed on the surface of the Sn—Cu alloy layer 53, and the surface roughness of the Sn—Cu alloy layer 53 is greater than that of the tin mass layer 54.

The wiring regions 52 of the plurality of connection terminal portions 41 arranged in each opening 43 of the solder resist layer 25 extend parallel to one another, and the connection regions 51 thereof are disposed in a staggered fashion. Namely, the connection regions 51 of two connection terminal portions 41 which are adjacent to each other in the arrangement direction of the connection terminal portions 41 are shifted from each other in a direction (the extending direction of the wiring region 52) perpendicular to the arrangement direction such that the positions of the connection regions 51 do not overlap in the arrangement direction. Also, connection terminal portions 41 configured such that a single wiring region 52 extends from one end of the connection region 51, and connection terminal portions 41 configured such that two wiring regions 52 extend from the opposite ends of the connection region 51 are alternately disposed in the arrangement direction. When the connection terminal portions 41 are formed in this manner, the terminal pitch of the connection terminal portions 41 can be decreased. Notably, in the present embodiment, the terminal pitch is, for example, 40 μm.

Next, a method of manufacturing the organic wiring substrate 10 of the present embodiment will be described.

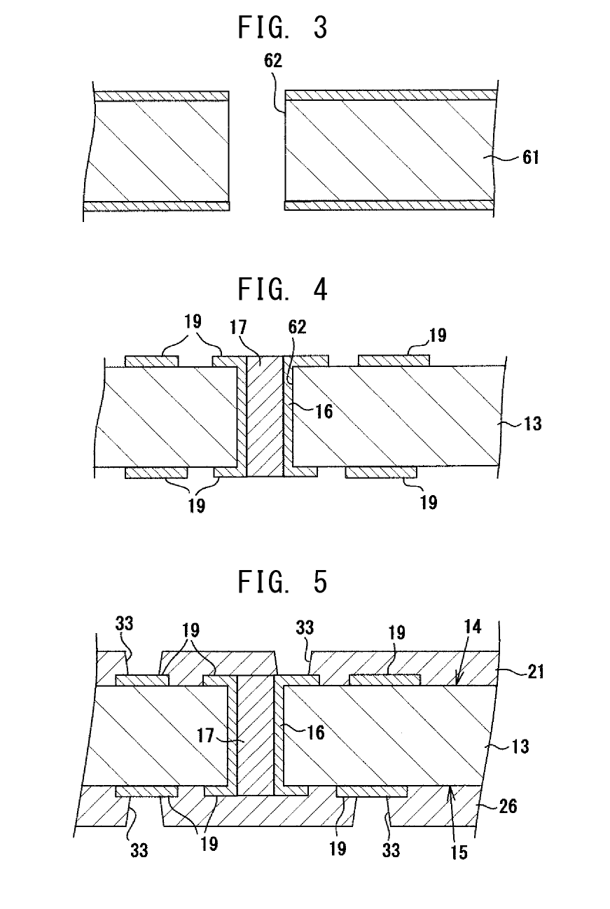

First, there is prepared a copper-clad laminate 61 which is composed of a substrate formed of glass epoxy and copper foils bonded to opposite surfaces of the substrate. Subsequently, drilling is performed using a drilling machine so as to form through-holes 62 (see FIG. 3) in the copper-clad laminate 61 at predetermined positions such that the through-holes 62 extend through the copper-clad laminate 61 between the front and back surfaces of the copper-clad laminate 61. Subsequently, electroless copper plating and copper electroplating are performed on the inner surfaces of the through-holes 62 of the copper-clad laminate 61 so as to form the through-hole conductors 16 in the through-holes 62.

After that, a resin insulation material (epoxy resin) is charged into the internal spaces of the through-hole conductors 16, whereby the plugs 17 are formed. Further, the copper foils of the copper-clad laminate 61 and the copper plating layers formed on the copper foils are patterned by, for example, a subtractive method. As a result, as shown in FIG. 4, the core substrate 13 having the conductor layers 19 and the through-hole conductors 16 is obtained.

Subsequently, by performing a build-up step, the first build-up layer 31 is formed on the main surface 14 of the core substrate 13, and the second build-up layer 32 is formed on the back surface 15 of the core substrate 13.

Specifically, the sheet-like resin insulation layers 21 and 26 formed of epoxy resin are disposed on and bonded to the main and back surfaces 14 and 15, respectively, of the core substrate 13. Subsequently, by performing laser machining through use of, for example, an excimer laser, a UV laser, or a CO₂ laser, the via holes 33 are formed in the resin insulation layers 21 and 26 at predetermined positions (see FIG. 5). Subsequently, by use of an etchant such as a potassium permanganate solution, a desmear step is carried out for removing smears from the via holes 33. In the desmear step, in place of treatment by use of an etchant, plasma asking by means of, for example, O₂ plasma may be performed.

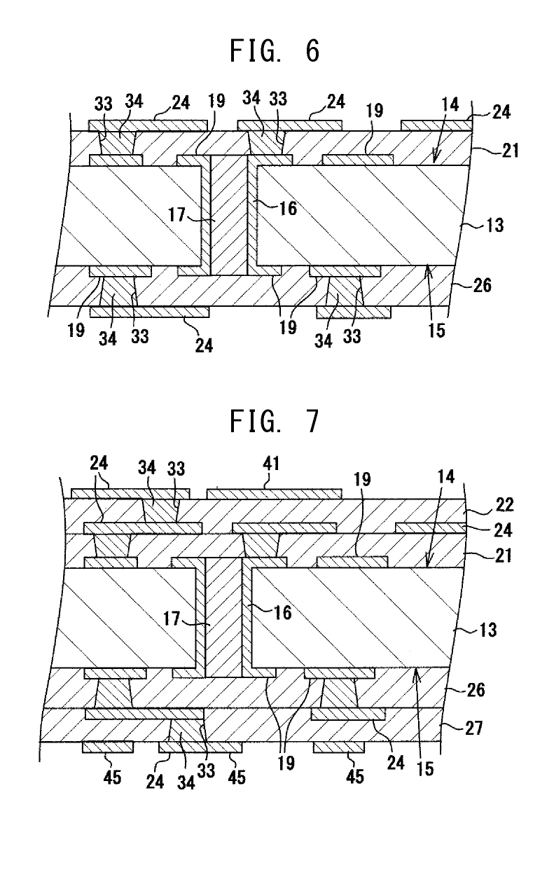

After the desmear step, the via conductors 34 are formed within the via holes 33 by performing electroless copper plating and copper electroplating in accordance with a conventionally known method. Moreover, the conductor layers 24 are formed in predetermined patterns on the resin insulation layers 21 and 26 by performing etching in accordance with a conventionally known method (for example, a semi-additive method) (see FIG. 6).

Other resin insulation layers 22 and 27 and conductor layers 24 are formed in a manner similar to that used for formation of the aforementioned resin insulation layers 21 and 26 and conductor layers 24, and are laminated on the resin insulation layers 21 and 26, respectively. Notably, at that time, the plurality of connection terminal portions 41 are formed as the conductor layer 24 on the resin insulation layers 22, and the plurality of external connection terminals 45 are formed as the conductor layer 24 on the resin insulation layers 27 (see FIG. 7).

Furthermore, the resin insulation layer 23 is formed in order to cover the side surface of each connection terminal portion 41 on the resin insulation layer 22. Specifically, a thermosetting resin is applied onto the surface of the resin insulation layer 22 so as to form a thin film thereon, and the thin film is thermally cured. After that, the cured thin film is polished until the top surfaces of the connection terminal portions 41 are exposed, whereby the resin insulation layer 23 is formed.

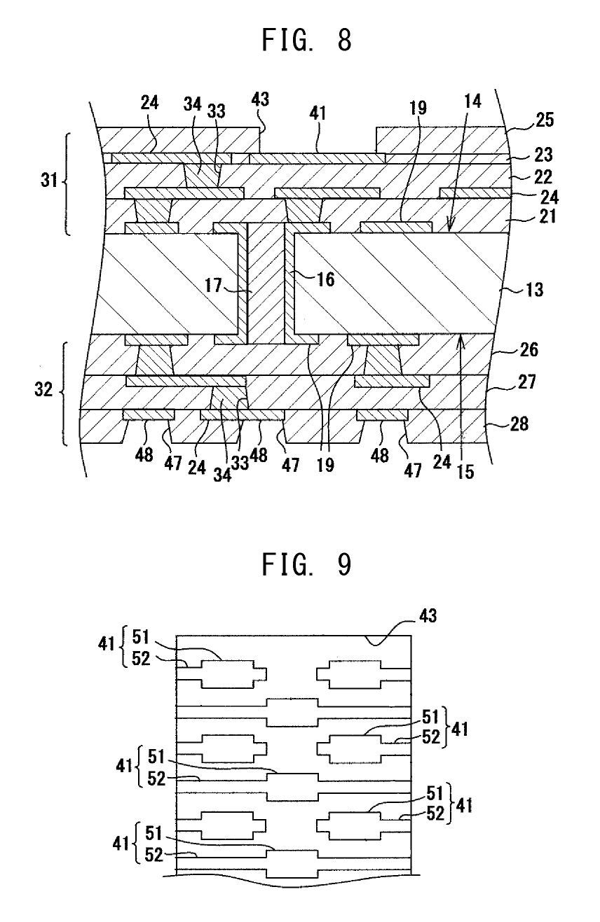

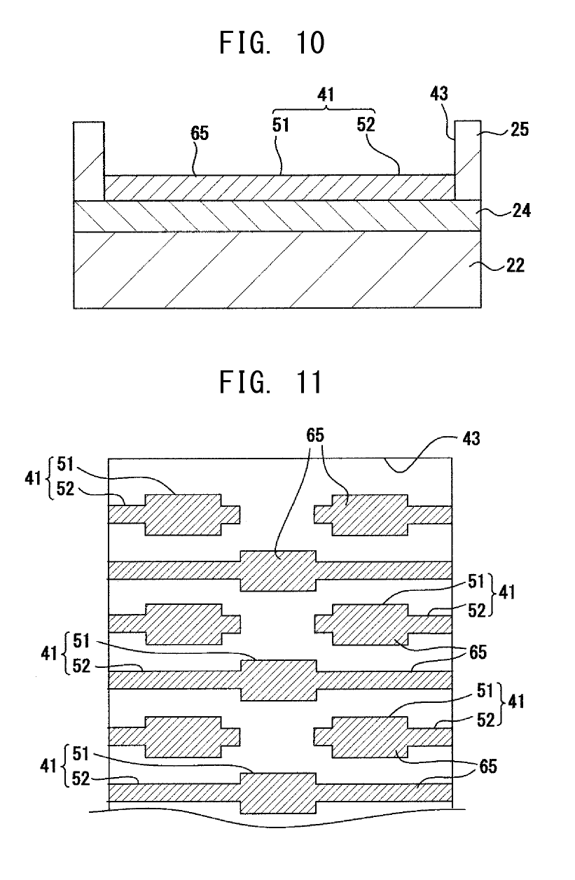

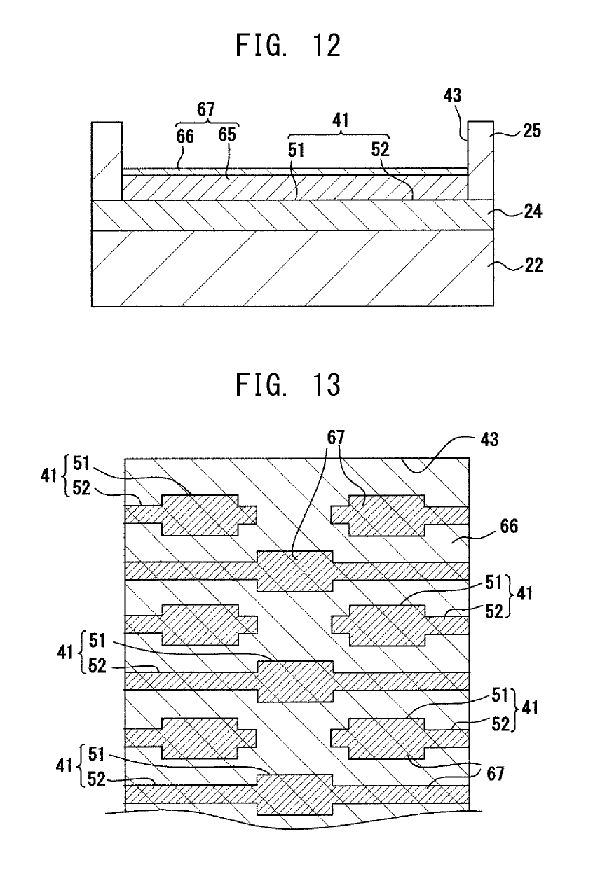

Next, a photosensitive epoxy resin is applied onto the resin insulation layers 23 and 27 and is cured, whereby the solder resist layers 25 and 28 are formed. Thereafter, predetermined masks are placed on the solder resist layers 25 and 28, and exposure and development are carried out, to thereby form the openings 43 and 47 in the solder resist layers 25 and 28 in respective patterns (see FIGS. 8 and 9). Subsequently, electroless tin plating is performed on the surface (upper surface) of each connection terminal portion 41 exposed through the corresponding opening 43, to thereby form a tin plating layer 65 (see FIGS. 10 and 11). Also, as a result of this electroless tin plating, the plating layer 48 is formed on the surface (lower surface) of each external connection terminal 45 exposed through the corresponding opening 47. Furthermore, as shown in FIGS. 12 and 13, a flux 66 is applied on the tin plating layer 65 so as to form on the surface of each connection terminal portion 41 (the connection region 51 and the wiring region 52) a preliminary metal layer 67 including the tin plating layer 65 and the flux 66 (preliminary metal layer forming step).

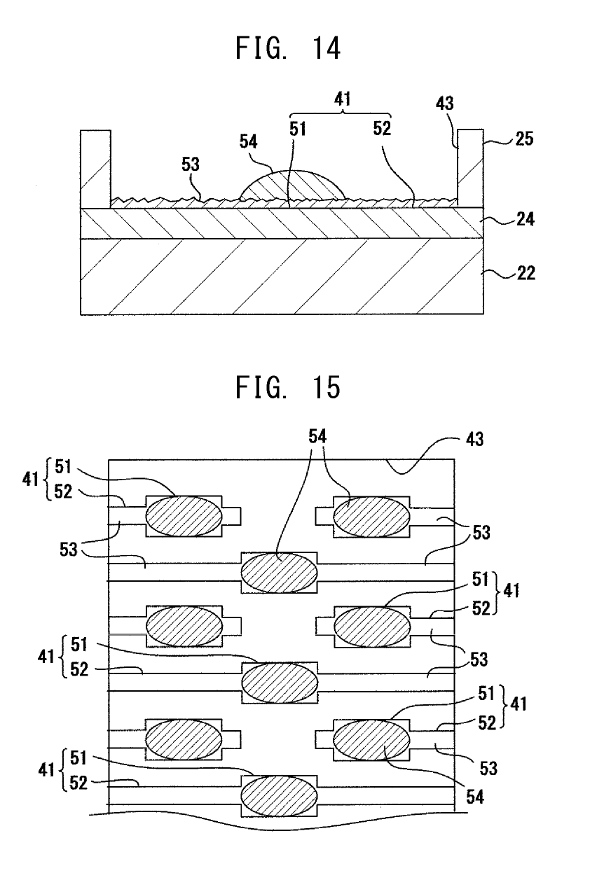

After that, a solder reflow step, which serves as a heating step, is carried out. In this step, the wiring substrate is heated to a temperature (for example, about 240° C.) that is higher than the melting point of tin and the melting point of the solder bumps 49. As a result, the Sn—Cu alloy layer 53 of copper and tin is formed on the surfaces of the connection region 51 and the wiring region 52. Also, at that time, the melted tin flows from the narrow wiring region 52 to the wide connection region 51 due to its surface tension. Since the tin on the surface of the wiring region 52 collects on the surface of the connection region 51, the tin mass layer 54 is formed on the surface of the connection region 51 (see FIGS. 14 and 15). Since the melted tin swells upward in a dome-like shape due to surface tension, the tin mass layer 54 is thicker than the Sn—Cu alloy layer 53. Also, fine projections and depressions are formed on the surface of the Sn—Cu alloy layer 53.

Also, in this reflow step, solder balls disposed on the external connection terminals 45 by use of an unillustrated solder ball placement apparatus are heated so as to form the solder bumps 49 on the external connection terminals 45. Through the above-described steps, the organic wiring substrate 10 shown in FIGS. 1 and 2 is manufactured.

Therefore, the present embodiment can yield at least the following effects.

(1) In the organic wiring substrate 10 of the present embodiment, since each connection terminal portion 41 is configured such that the connection region 51, to which a connection terminal of a semiconductor chip is connected, is wider than the wiring region 52, a sufficiently large area can be provided for solder connection. Also, the alloy layer 53 of copper and tin is exposed on the surface of the wiring region 52, and the tin mass layer 54 is exposed on the surface of the connection region 51. This configuration makes the solder wettability of the wiring region 52 lower than that of the connection region 51. Therefore, even when a temperature equal to or higher than the melting point of solder is applied to the wiring substrate after mounting of a semiconductor chip on the substrate, problems such as outflow of solder from the connection region 51 to the wiring region 52 do not occur, and the solder in the connection region 51 can be retained reliably. Therefore, a highly reliable connection can be established between the wiring substrate and the semiconductor chip. Moreover, since copper and tin which constitute the connection terminal portions 41 are relatively inexpensive metals, the production cost of the wiring substrate 10 can be reduced.

(2) In the organic wiring substrate 10 of the present embodiment, projections and depressions are formed on the surface of the wiring region 52 of each connection terminal portion 41 such that the surface roughness of the surface increases. This configuration yields the following advantageous effect. In the case where the gap between the wiring substrate 10 and the semiconductor chip mounted thereon is sealed with an underfill material, the degree of adhesion between the wiring region 52 and the underfill material can be increased. Also, in this case, since a gap becomes unlikely to be formed between the surface of the wiring region 52 and the underfill material, it is possible to reliably avoid the occurrence of problems, such as outflow of solder from the connection region 51 to the wiring region 52, which would otherwise occur due to thermal history.

(3) In the organic wiring substrate 10 of the present embodiment, the tin mass layer 54 formed on the surface of the connection region 51 of each connection terminal portion 41 is thicker than the alloy layer 53 formed on the surfaces of the connection region 51 and the wiring region 52 of each connection terminal portion 41. By virtue of this configuration, the connection terminals of a semiconductor chip can be reliably solder-connected to the connection regions 51 of the connection terminal portions 41.

(4) In the organic wiring substrate 10 of the present embodiment, a plurality of connection terminal portions 41 are arranged such that their wiring regions 52 extend parallel to one another. Also, the connection regions 51 of two connection terminal portions 41 which are adjacent to each other in the arrangement direction are shifted from each other in a direction (the extending direction of the wiring region 52) perpendicular to the arrangement direction of the connection terminal portions 41 such that the positions of the connection regions 51 do not overlap in the arrangement direction. This configuration enables the plurality of connection terminal portions 41 each including the wide connection region 51 to be provided in a smaller space. Therefore, the mounting density of the organic wiring substrate 10 can be increased.

(5) In the present embodiment, the heating step (solder reflow step) is performed after the preliminary metal layer 67 including the tin plating layer 65 and the flux 66 applied thereon is formed in the preliminary metal layer forming step. At that time, the Sn—Cu alloy layer 53 of copper and tin is formed on the surfaces of the connection region 51 and the wiring region 52, and the melted tin collects in the wide connection region 51 due to its surface tension. As a result, the Sn—Cu alloy layer 53, which is low in solder wettability, can be exposed on the surface of the wiring region 52, and the tin mass layer 54, which is high in solder wettability, can be exposed on the surface of the connection region 51.

(6) In the organic wiring substrate 10 of the present embodiment, the side surface of each connection terminal portion 41 is covered by the resin insulation layer 23. By virtue of this configuration, only the upper surface of the connection terminal portion 41 is exposed in the connection region 51 and the wiring region 52, and the area ratio of the exposed surface of the connection region to the exposed surface of the wiring region can be increased. Therefore, melted tin can be reliably collected to the surface of the connection region 51 having a large area.

(7) In the present embodiment, in the preliminary metal layer forming step, electroless tin plating is performed on the surface of each connection terminal portion 41, whereby the tin plating layer 65 having a uniform thickness can be formed on the surface. Accordingly, it is possible to reliably suppress variation in the thickness of the tin mass layer 54 which is formed on each connection region 51 through the heating step.

(8) In the present embodiment, the heating step for forming the tin mass layer 54 in the connection region 51 is realized by the reflow step for providing the solder bumps 49 on the external connection terminals 45. In this case, the heating step and the reflow step, which has conventionally been performed for manufacture of substrates, are not required to be performed in different heat treatment steps. Therefore, the manufacturing cost of the wiring substrate 10 can be reduced.

The embodiment of the present invention may be modified at least as follows.

In the above-described embodiment, the alloy layer 53 of copper and tin is formed as the first metal layer. However, the first metal layer is not limited thereto. Specifically, the preliminary metal layer forming step and the heating step may be performed after formation of, for example, a gold plating layer or a silver plating layer on the surface of each connection terminal portion 41. In this case, an alloy layer containing gold or silver is formed on the surface of each connection terminal portion 41.

In the above-described embodiment, tin is used as the solder material including metal that constitutes the second metal layer. However, a solder material including metal (low melting point metal), such as lead or bismuth, which can be used as a solder material may be used in place of tin. In the above-described embodiment, the tin plating layer 65, which constitutes the preliminary metal layer 67, is formed by performing electroless tin plating. However, the tin plating layer 65 may be formed by tin electroplating.

In the organic wiring substrate 10 of the above-described embodiment, the solder wettability of the wiring region 52 of each connection terminal portion 41 is rendered lower than that of the connection region 51 of each connection terminal portion 41 by performing the preliminary metal layer forming step and the heating step. However, the method of rendering the solder wettability of the wiring region 52 lower than that of the connection region 51 is not limited thereto. For example, the solder wettability of the wiring region 52 may be made lower than that of the connection region 51 by changing the solder wettability of the surface of each connection terminal portion 41 through physical or chemical surface treatment. Specifically, after a metal layer having a high solder wettability is formed on the surfaces of the connection region 51 and wiring region 52 of each connection terminal portion 41, a laser beam is applied to the surface of the wiring region 52. As a result, a metallic oxide layer is formed on the surface of the wiring region 52, whereby the solder wettability of the wiring region 52 is made lower than that of the connection region 51. Alternatively, after a metal layer having a low solder wettability and a metal layer having a high solder wettability are formed on the surfaces of the connection region 51 and wiring region 52 of each connection terminal portion 41, a laser beam is applied to the surface of the wiring region 52. As a result, the metal layer having a low solder wettability is exposed on the surface of the wiring region 52, whereby the solder wettability of the wiring region 52 is made lower than that of the connection region 51. In these cases as well, problems such as outflow of solder from the connection region 51 to the wiring region 52 can be avoided, and highly reliable connection can be established between the wiring substrate and a semiconductor chip.

In the above-described embodiment, the resin insulation layer 23, which covers the side surface of each connection terminal portion 41, is formed by applying a thermosetting resin onto the surface of the resin insulation layer 22 so as to form a thin film thereon, thermally curing the thin film, and then polishing the cured thin film until the connection terminal portions 41 are exposed. However, the method of forming the resin insulation layer 23 can be changed freely. For example, the resin insulation layer 23, which covers the side surface of each connection terminal portion 41, may be formed by applying a thermosetting resin onto the surface of the resin insulation layer 22 so as to form a thin film thereon, removing a portion of the resin insulation layer covering the upper surface of each connection terminal portion 41 through use of a solvent, and thermally curing the thin film. Alternatively, the resin insulation layer 23, which covers the side surface of each connection terminal portion 41, may be formed by applying a thermosetting resin onto the surface of the resin insulation layer 22 so as to form a thick film thereon, thermally curing the film, and then removing a portion of the resin insulation layer existing on the upper surface of each connection terminal portion 41 by dry etching. Notably, in this case, the resin insulation layer and the solder resist layer 25 are formed as a single layer.

In the organic wiring substrate 10 of the above-described embodiment, the side surface of each connection terminal portion 41 is covered by the resin insulation layer 23. However, the side surface of each connection terminal portion 41 may be exposed from the resin insulation layer 23.

The organic wiring substrate 10 of the above-described embodiment is a wiring substrate including the core substrate 13. However, the organic wiring substrate 10 is not limited thereto, and the present invention may be applied to a coreless wiring substrate having no core.

The organic wiring substrate 10 of the above-described embodiment is of a BGA (ball grid array) type. However, the type of the wiring substrate is not limited thereto, and the present invention may be applied to a wiring substrate of a PGS (pin grid allay) type, a wiring substrate of an LGA (land grid array), or the like.

In the above-described embodiment, the heating step for forming the tin mass layer 54 in the connection region 51 and the solder reflow step for providing the solder bumps 49 on the external connection terminals 45 are performed in a single thermal treatment step. However, the heating step and the reflow step may be performed in different thermal treatment steps.

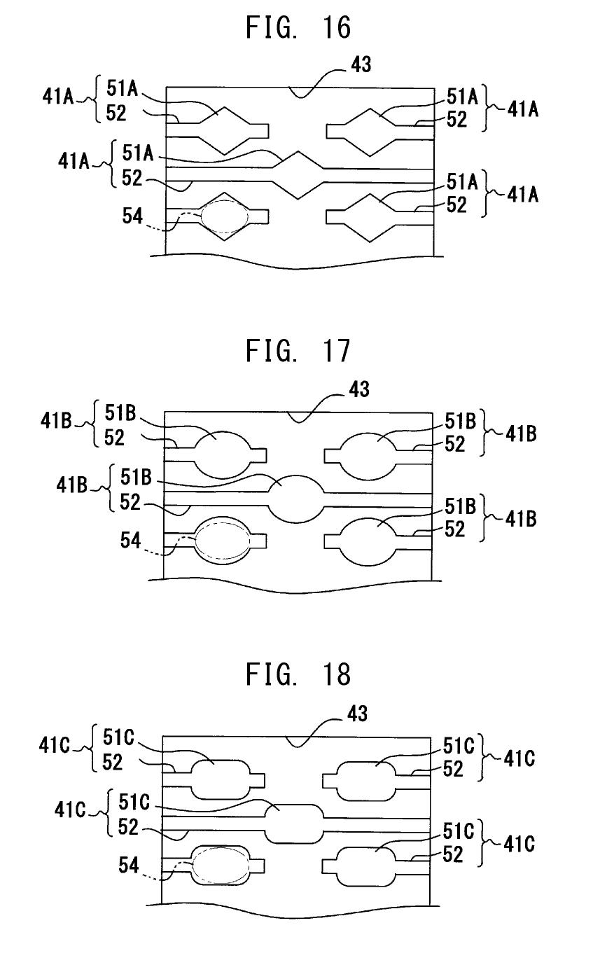

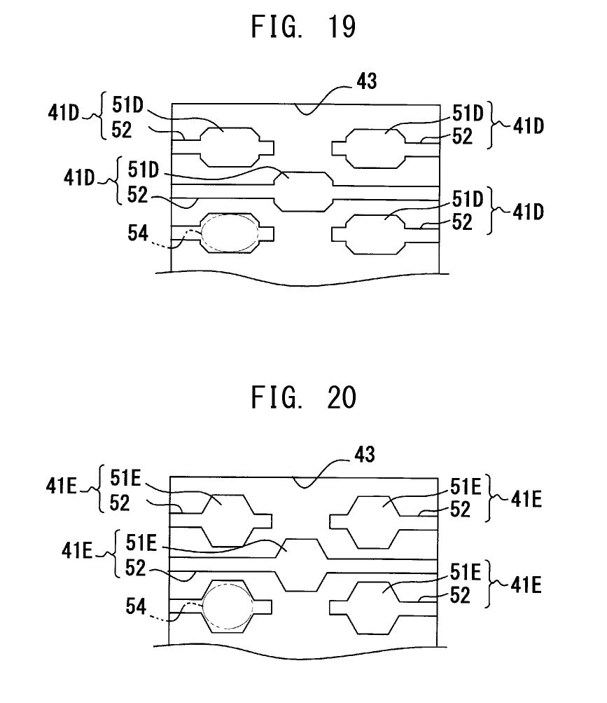

In the above-described embodiment, each connection terminal portion 41 has a rectangular connection region 51 as viewed from above. However, the shape of the connection region 51 is not limited thereto. For example, each of connection terminal portions 41A of another embodiment shown in FIG. 16 has a connection region 51A having a rhombic shape as viewed from above. Since these connection terminal portions 41A are short in the widest portion length, solder bumps having a sufficient height can be readily formed. Each of connection terminal portions 41B of another embodiment shown in FIG. 17 has a connection region 51B having an elliptical shape as viewed from above. The length of the connection region 51B is greater than the width thereof. Each of connection terminal portions 41C of another embodiment shown in FIG. 18 has a connection region 51C. As viewed from above, the connection region 51C has the shape of a rectangle with four rounded corners (namely, rounded portions are provided at the four corners). The length of the connection region 51C is greater than the width thereof. Each of connection terminal portions 41D of another embodiment shown in FIG. 19 has a connection region 51D. As viewed from above, the connection region 51D has the shape of a rectangle with four chamfered corners (namely, chamfered portions are provided at the four corners). The length of the connection region 51D is greater than the width thereof. Each of connection terminal portions 41E of another embodiment shown in FIG. 20 has a connection region 51E having a regular hexagonal shape as viewed from above.

Next, some of the technical ideas that the embodiment described above implements, are enumerated below.

(1) The wiring substrate described in Means 1 is characterized in that the wiring substrate is an organic wiring substrate which uses a resin insulation layer as the insulation layer.

(2) The wiring substrate described in Means 1 is characterized in that the first metal layer is formed on the surfaces of the connection region and the wiring region, the first metal layer is exposed on the surface of the wiring region, the second metal layer is formed on the surface of the connection region via the first metal layer such that the second metal layer is exposed, the solder wettability of the surface of the first metal layer is lower than that of the surface of the second metal layer, and the second metal layer is thicker than the first metal layer.

(3) The wiring substrate described in Means 1 is characterized in that the wiring region extends from one side or both sides of the connection region.

(4) The wiring substrate described in Means 1 is characterized in that the terminal pitch of the plurality of connection terminal portions is 80 μm or less.

(5) The wiring substrate described in Means 1 is characterized in that the plurality of connection terminal portions are arranged such that their wiring regions extend parallel to one another, and the connection regions of two connection terminal portions which are adjacent to each other in the arrangement direction are shifted from each other in the direction perpendicular to the arrangement direction of the connection terminal portions such that the positions of the connection regions do not overlap in the arrangement direction.

(6) A method of manufacturing the wiring substrate described in Means 1 is characterized by comprising a surface treatment step of performing surface treatment such that the solder wettability of the wiring region becomes lower than that of the connection region.

(7) A wiring substrate manufacturing method described in Means 2 or 3 is characterized in that the wiring substrate has a main surface on which the connection terminal portions are formed and a back surface which is provided on the side opposite the main surface and which has a plurality of external connection terminals formed thereon so as to allow solder bumps to be disposed on the external connection terminals, and the heating step also serves as a solder reflow step for providing the solder bumps on the external connection terminals.

### DESCRIPTION OF REFERENCE NUMERALS

10: organic wiring substrate serving as a wiring substrate

21 to 23, 26, 27: resin insulation layer serving as an insulation layer

24: conductor layer

25, 28: solder resist layer serving as an insulation layer

31: first build-up layer serving as a laminate

41, 41A, 41B, 41C, 41D, 41E: connection terminal portion

43: opening

51, 51A, 51B, 51C, 51D, 51E: connection region

52: wiring region

53: alloy layer serving as a first metal layer and an intermetallic compound layer

54: tin mass layer serving as a second metal layer

65: tin plating layer

66: flux

67: preliminary metal layer

R1: semiconductor chip mounting region

What is claimed is:

1. A wiring substrate, comprising:
a laminate in which a plurality of insulation layers and a plurality of conductor layers are laminated alternately, an outermost conductor layer of the laminate including a plurality of connection terminal portions which are arranged along a periphery of a semiconductor chip mounting region and to which a semiconductor chip is flip-chip connected, the plurality of connection terminal portions being disposed in openings formed in an outermost insulation layer of the laminate;
wherein:
each of the plurality of connection terminal portions includes a connection region to which a connection terminal of the semiconductor chip is to be connected via solder, and a wiring region which extends in a planar direction from the connection region and which is narrower than the connection region; and
the surface of the wiring region has a solder wettability lower than that of the surface of the connection region.

2. The wiring substrate according to claim 1, wherein:
a first metal layer is formed on the surfaces of the connection region and the wiring region such that the first metal layer is exposed on the surface of the wiring region;
a second metal layer is formed on the surface of the connection region via the first metal layer such that the second metal layer is exposed; and
the surface of the first metal layer has a solder wettability lower than that of the surface of the second metal layer.

3. The wiring substrate according to claim 2, wherein the first metal layer is an intermetallic compound layer including a metal which constitutes the plurality of connection terminal portions and a metal which constitutes the second metal layer.

4. The wiring substrate according to claim 3, wherein the metal which constitutes the plurality of connection terminal portions is copper or a copper alloy, the metal which constitutes the second metal layer is a solder material including metal which can be used as a solder material, other than copper, and the intermetallic compound layer is an alloy layer of copper and the solder material including metal.

5. The wiring substrate according to claim 3, wherein the metal which constitutes the plurality of connection terminal portions is copper or a copper alloy, the metal which constitutes the second metal layer is tin, and the intermetallic compound layer is an alloy layer of copper and tin.

6. The wiring substrate according to claim 1, wherein a side surface of each of the plurality of connection terminal portions is covered by an insulation layer.

7. The wiring substrate according to claim 2, wherein the first metal layer has a surface roughness greater than that of the second metal layer.

8. The wiring substrate according to claim 1, wherein, as viewed from above, the connection region has a rhombic shape, a circular shape, a shape of a quadrangle with four rounded corners, a shape of a quadrangle with four chamfered corners, or a shape of a polygon having three or more corners.

9. A method of manufacturing a wiring substrate, the wiring substrate comprising:
a laminate in which a plurality of insulation layers and a plurality of conductor layers are laminated alternately, an outermost conductor layer of the laminate including a plurality of connection terminal portions which are arranged along a periphery of a semiconductor chip mounting region and to which a semiconductor chip is flip-chip connected, the plurality of connection terminal portions being disposed in openings formed in an outermost insulation layer of the laminate;
wherein:
each of the plurality of connection terminal portions includes a connection region to which a connection terminal of the semiconductor chip is to be connected via solder, and a wiring region which extends in a planar direction from the connection region and which is narrower than the connection region;
the surface of the wiring region has a solder wettability lower than that of the surface of the connection region;
a first metal layer is formed on the surfaces of the connection region and the wiring region such that the first metal layer is exposed on the surface of the wiring region;
a second metal layer is formed on the surface of the connection region via the first metal layer such that the second metal layer is exposed;
the surface of the first metal layer has a solder wettability lower than that of the surface of the second metal layer;
the first metal layer is an intermetallic compound layer including a metal which constitutes the plurality of connection terminal portions and a metal which constitutes the second metal layer; and
the metal which constitutes the plurality of connection terminal portions is copper or a copper alloy, the metal which constitutes the second metal layer is a solder material including metal which can be used as a solder material, other than copper, and the intermetallic compound layer is an alloy layer of copper and the solder material including metal;
the method comprising:
a preliminary metal layer forming step of forming, on the surfaces of the connection region and the wiring region, a preliminary metal layer including the solder material including metal and a flux; and
a heating step of performing, after the preliminary metal layer forming step, heating at a temperature higher than a melting point of the solder material including metal so as to form the first metal layer, which includes copper and the solder material including metal, on the surfaces of the connection region and the wiring region, and to allow the solder material including metal melted on the surface of the wiring region to collect on the surface of the connection region to thereby form the second metal layer.

10. The method of manufacturing a wiring substrate according to claim 9, wherein, in the preliminary metal layer forming step, the flux is applied on to the solder material including metal to form the preliminary metal layer.

11. The method of manufacturing a wiring substrate according to claim 9, wherein:
the solder material including metal is tin;
the preliminary metal layer includes a tin plating layer having the flux applied thereon;
the temperature higher than the melting point of the solder material including metal is a temperature higher than a melting point of tin; and
the second metal layer includes a tin mass layer.
